(19) United States
(12) Patent Application Publication
(10) Pub. No.: US 2025/0286343 A1
(43) Pub. Date: Sep. 11, 2025

(54) LASER DEVICE AND METHOD FOR CONTROLLING THE SAME

(71) Applicant: STABILA Messgeräte Gustav Ullrich GmbH, Annweiler (DE)

(72) Inventors: Daniel BUSAM, Godramstein (DE); Gabriel KALLABIS, Spirkelbach (DE)

(73) Assignee: STABILA Messgeräte Gustav Ullrich GmbH, Annweiler (DE)

(21) Appl. No.: 19/075,029

(22) Filed: Mar. 10, 2025

(30) Foreign Application Priority Data
Mar. 11, 2024 (DE) 10 2024 106 860.4

(51) Int. Cl. H01S 5/042; G01C 15/00

(52) U.S. Cl. CPC H01S 5/042; G01C 15/004

(57) ABSTRACT

The invention relates to a laser device (10) and a method for controlling such a device. The laser device (10) comprises at least one laser diode (14) for emitting a laser beam (16, 20), a laser diode controller (24) for controlling at least the operation of the laser diode (14), a temperature sensor (32) for detecting a temperature Ti associated with the laser device (10), such as the internal temperature of the laser leveling tool, wherein the laser diode controller (24) is configured to operate the at least one laser diode (14) with an operating power Pb and to reduce the operating power Pb of the laser diode (14) to a reduced operating power Pred when the detected temperature Ti reaches a temperature threshold value Ts. In order to operate the at least one laser diode at an optimal operating point that does not lead to inadmissible heating, it is provided that the laser diode control (24) is configured such that after reducing the operating power Pb, the temperature Ti is compared with the temperature threshold value Ts at time intervals Δt and the reduced operating power Pred of the laser diode (14) is further reduced if the temperature Ti is greater than the temperature threshold value Ts after the comparison is made.

The invention relates to a laser device, such as a laser leveling tool, comprising at least one laser diode for emitting a laser beam, a laser diode controller for controlling at least the operation of the laser diode, a temperature sensor for detecting a temperature Ti associated with the laser device, such as an internal temperature of the laser device such as laser leveling tool, wherein the laser diode controller is configured to operate the at least one laser diode with an operating power Pb and to reduce the operating power Pb of the laser diode to a reduced operating power Pred when the detected temperature Ti reaches a temperature threshold Ts.

Furthermore, the invention relates to a method for controlling a laser device, such as a laser leveling tool, comprising the steps:
controlling at least one laser diode by means of a laser diode controller for emitting a laser beam,
detecting a temperature Ti associated with the laser device, such as the internal temperature of the laser device, such as the laser leveling tool, by means of a temperature sensor, wherein the laser diode controller operates the laser diode with an operating power Pb and the operating power Pb of the laser diode is reduced to a reduced operating power Pred when the detected temperature Ti reaches a temperature threshold Ts.

EP 3 276 304 A1 (US 2018/0120103 A1) relates to a laser leveling tool with at least one laser diode for emitting a laser beam, a control unit for controlling at least the operation of the laser diode and a heat sensor for detecting the internal temperature of the laser leveling tool. In order to enable continued operation of the laser leveling tool even when temperatures increase, it is provided that the control unit is configured to reduce the operating power of the laser diode when the detected internal temperature reaches a temperature threshold.

The temperature threshold has at least two different temperature threshold values corresponding to different operating current levels of the laser diode, wherein the control unit is configured to reduce the operating current of the laser diode to a corresponding operating current level when the detected internal temperature reaches one of the temperature threshold values. The operating current of the laser diode can be reduced by lowering the duty cycle or the electrical current of the laser diode.

WO 2022/237285 A1 relates to a method for controlling a laser diode and a corresponding control system. In order to reduce the energy consumption of the laser diode during operation and to avoid overheating of the laser diode during operation, it is proposed that the laser diode is operated with a first control voltage and a first duty cycle, wherein the operating time of the laser diode is detected and wherein, when the operating time of the laser diode exceeds a first time threshold, the laser diode is operated with a second control voltage and a second duty cycle, wherein the second control voltage is less than the first control voltage and/or the second duty cycle is less than the first duty cycle.

EP 4 258 080 A1 relates to a temperature control for a laser component, such as a laser leveling device. The temperature is converted into a measuring voltage and compared with a temperature threshold voltage, whereby the power of the laser component is reduced if the threshold value is exceeded.

The subject matter of US 2024/0013017 A1 is a symbol laser, such as a barcode scanner. In order to be able to use the device in an environment where temperatures are below the operating temperature of the device's components, a power source is provided to generate current that is below the laser threshold of the device.

WO 2021/103734 A1 relates to a laser spirit level that can be used in a wide operating temperature range.

A method for operating an infrared vision system for motor vehicles is the subject of DE 10 2005 033 896 A1.

The object of the present invention is to develop a device and a method of the type mentioned at the outset in such a way that a simplified control is made possible compared to the prior art, which ensures that the operating power of the laser diode does not lead to inadmissible heating.

The object is essentially achieved according to the invention by a laser device, such as a laser leveling tool, comprising: at least one laser diode for emitting a laser beam, a laser diode controller for controlling at least the operation of the laser diode, a temperature sensor for detecting a temperature Ti associated with the laser device, such as the internal temperature of the laser device, such as a laser leveling tool, wherein the laser diode controller is configured to operate the at least one laser diode with an operating power Pb and to reduce the operating power Pb of the laser diode to a reduced operating power Pred when the detected temperature Ti reaches a temperature threshold Ts, wherein the laser device is characterized in that the laser diode controller is configured such that after the laser diode is switched on or after the operating power Pb is reduced for the first time, the temperature Ti is compared with the temperature threshold Ts at time intervals Δt and that the operating power Pred of the laser diode is reduced if the temperature Ti is equal to or greater than the temperature threshold value Ts after the comparison is made.

According to the invention, it is provided that the laser diode controller is configured such that after reducing the operating power Pb, the temperature Ti is compared with the temperature threshold value Ts at preferably equal time intervals Δt and that the reduced operating power Pred of the laser diode is reduced if the temperature Ti is greater than the temperature threshold value Ts after the comparison is made.

The invention is based on the idea that only a single temperature threshold is defined and monitored. As soon as the temperature associated with the laser device, such as the internal temperature of the laser device, reaches this single temperature threshold, the operating power of the laser diode is reduced.

Further temperature measurements are then taken at intervals of, for example, 30 minutes. If the measured temperature is above the single temperature threshold, the operating power of the laser diode is further reduced each time, e.g. by 30% of the nominal power or of current operating power of the laser diode. If the temperature continues to rise, particularly inside the housing of the laser device, e.g. due to environmental influences, the operating power of the laser diode will be further reduced, possibly to zero.

If the temperature does not rise to such an extent that the temperature threshold is reached due to the reduction in operating power, no reduction will occur.

However, the invention also provides that after switching on the laser diode, at time intervals Δt, in particular with 10 min≤Δt≤60 min, the temperature Ti, which is associated with the laser device and thus determined, is compared with the temperature threshold value Ts, and that the operating power Pred of the laser diode is then reduced if the temperature Ti is equal to or greater than the temperature threshold value Ts after the comparison is made.

A preferred embodiment is characterized in that the laser diode controller has a timer for setting the time interval Δt, wherein preferably Δt≤60 min, in particular 10 min≤Δt≤45 min, particularly preferably Δt=30 min, and/or that the time intervals Δt are constant or variable, preferably constant.

The temperature threshold Ts is in the range Ts≤Tmax, in particular Ts<Tmax, preferably in the range 70% Tmax≤Ts≤95% Tmax, where Tmax is the maximum permissible operating temperature of the laser diode.

Particularly preferably, the laser diode controller comprises a control unit and a laser diode driver which are configured to reduce the operating power Pb of the laser diode in steps, linearly or according to a function.

Preferably, the operating power Pb is reduced in constant power reductions or in variable power reductions, wherein the variable power reductions are increased if a temperature difference ΔTis between the measured temperature Ti above the temperature threshold Ts and the temperature threshold Ts increases when the temperatures Ti, Ts are compared in succession.

Preferably, the power reductions are in the range of 5% Pmax≤ΔPb≤30% Pmax, where Pmax is the maximum operating power of the laser diode or the set operating power of the laser diode.

Preferably, the control unit and/or the laser diode driver are configured such that the amplitude of the electric current and/or the voltage of the laser diode and/or a pulse width of the electric current and/or the voltage can be adjusted, in particular reduced.

The temperature sensor is preferably located inside the laser device, in particular adjacent to or in the region of the at least one laser diode.

A method for controlling a laser device, such as a laser leveling tool, comprising the steps: controlling at least one laser diode by means of a laser diode controller to emit a laser beam, detecting a temperature Ti associated with the laser device, such as the internal temperature of the laser leveling tool, by means of a temperature sensor, wherein the laser diode controller operates the laser diode with an operating power Pb and the operating power Pb of the laser diode is reduced to a reduced operating power Pred when the detected temperature Ti reaches a temperature threshold value Ts, is characterized in that after switching on the laser diode or after the operating power Pb is reduced for the first time, the temperature Ti is compared with the temperature threshold value Ts at time intervals Δt and that the operating power Pred of the laser diode is reduced if the temperature Ti is equal to or greater than the temperature threshold Ts after the comparison is made.

It is preferably provided that the reduction of the operating power Pb takes place in steps, linearly or according to a predefined function and/or that the reduction of the operating power Pb takes place at constant or variable, preferably constant, time intervals Δt.

In particular it is provided that the operating power Pb is reduced in constant power reductions or in variable power reductions, wherein the variable power reductions are increased if a temperature difference ΔTis between the measured temperature Ti above the temperature threshold Ts and the temperature threshold value Ts increases when the temperatures Ti, Ts are compared in succession.

Preferably it is provided that the power reduction is in the range of 5% Pmax≤ΔPb≤50% Pmax, where Pmax is the maximum operating power of the laser diode or the set operating power of the laser diode.

Preferably, the power reduction can be carried out as a function of the temperature difference ΔTis.

Additional details, advantages, and features of the invention will be apparent not only from the claims and the features specified therein—alone and/or in combination—but also from the following description of a preferred exemplary embodiment.

In the figures:

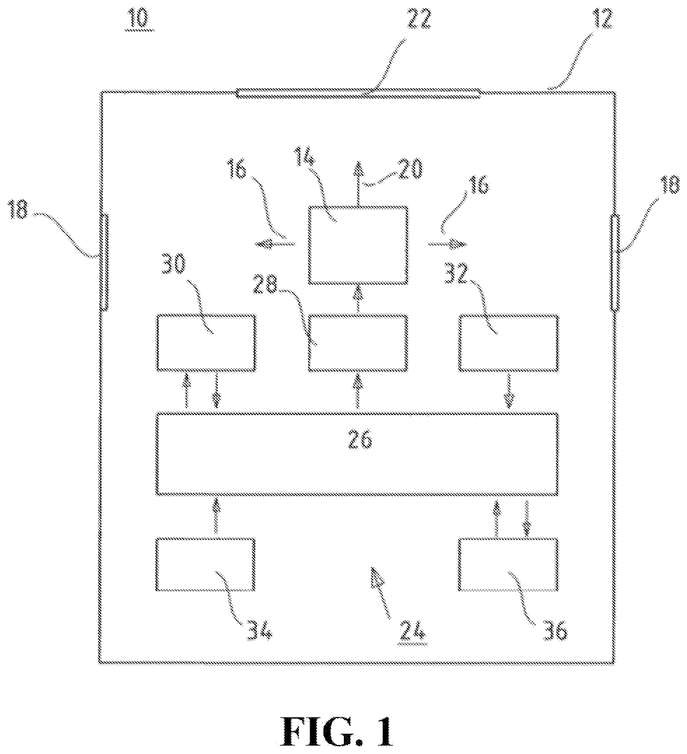

FIG. 1 shows a schematic diagram of a laser leveling device,

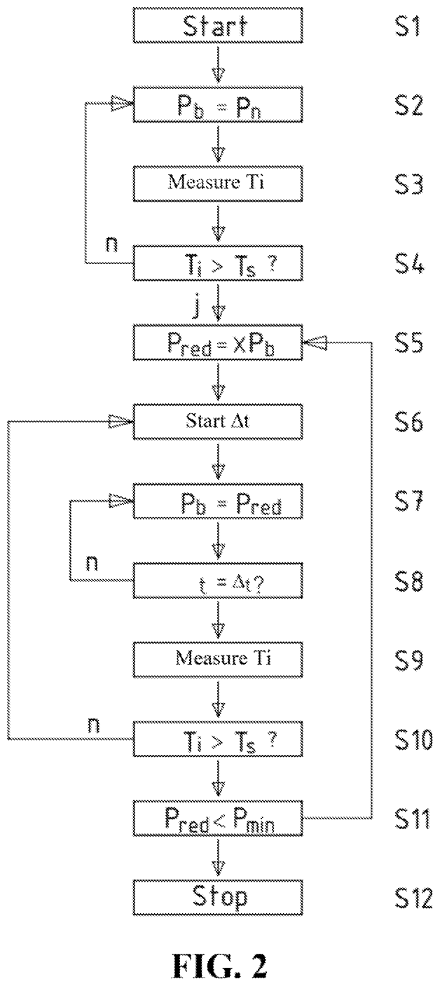

FIG. 2 shows a flow chart of a laser diode control and

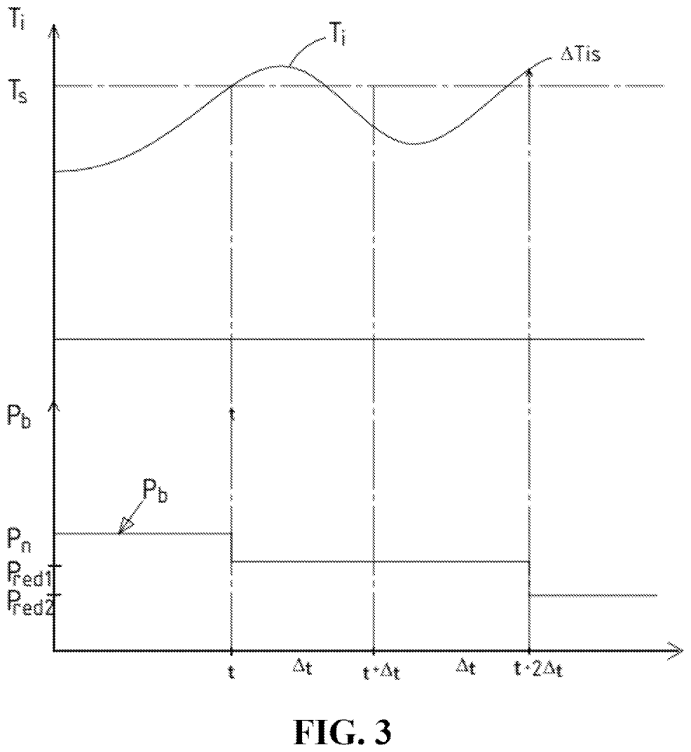

FIG. 3 shows a diagram of the internal temperature of the laser leveling device and the operating power of the laser diode over time t.

FIG. 1 shows a schematic diagram of a laser device 10, in particular a laser leveling device, with a housing 12 in which at least one laser diode 14 is arranged. The laser device 10 can be operated as a line laser, with one or more laser beams 16 emitted from the laser diodes 14 exiting through lateral output windows 18. Alternatively, the laser device 10 can also be operated as a point laser, wherein a laser beam 20 emanating from the laser diode 14 leaves the housing 12 as a plumb beam via an output window 22.

The at least one laser diode 14 is operated via a laser diode controller 24. This comprises a control unit 26, a laser diode driver 28 for operating the laser diode 14, a timer 30 for setting a time interval Δt, a temperature sensor 32 for measuring the internal temperature Ti of the housing 12, a power supply 34, such as a battery or rechargeable battery, for supplying the laser device 10 with energy, and an operating and display unit 36.

The function of the laser diode controller 24 and a method for controlling the laser diode 14 are explained below using the flow chart according to FIG. 2 and the temperature and power diagrams according to FIG. 3.

FIG. 2 shows a flow chart of a method for controlling the laser device 10. Corresponding temperature and power curves over time are shown in FIG. 3. After starting the laser device 10 in step S1, the laser diode 14 is operated in step S2 with an operating power Pb which preferably corresponds to the nominal power Pn of the laser diode 14. During operation, the temperature Ti, for example, inside the housing 12 is measured with the temperature sensor 32 (step S3). The measured temperature Ti is continuously compared with a temperature threshold value Ts (step S4). If the measured temperature Ti is less than the temperature threshold Ts, the laser diode 14 continues to operate at nominal power Pn (step S2).

As soon as the temperature Ti inside the laser device 10 exceeds the temperature threshold Ts for the first time, the operating power Pb is reduced for the first time to a first reduced operating power Pred1 in step S5.

The power reductions are in the range of 5% Pmax≤ΔPb≤50% Pmax, where Pmax is the maximum operating power of the laser diode or the set operating power of the laser diode. The power reduction can be set depending on a temperature difference ΔTis between the measured temperature Ti above the temperature threshold Ts and the temperature threshold value Ts. If the measured temperature Ti is, for example, 5% above the temperature threshold value Ts, the power reduction can be set lower than if the measured temperature Ti is, for example, 10% above the temperature threshold value Ts.

At the same time, in step S6, a timer 30 is started so that the laser diode 14 is operated with the reduced operating power Pred1 at least over a defined time interval Δt, e.g. 30 min (step S7). After the time interval Δt has elapsed in step S8, the current temperature Ti is queried in step S9 and the current temperature Ti is compared with the temperature threshold value Ts in step S10. If the temperature Ti is less than the temperature threshold Ts, the method is continued by restarting the timer 30 in step S6 and operating the laser diode with the previously set reduced operating power Pred1. In other words, if the temperature Ti does not increase further due to the reduction of the operating power Pb, a further reduction of the operating power Pb does not occur.

However, if it is determined in step S10 that the current temperature Ti is greater than the temperature threshold Ts, e.g. due to environmental influences, the method is continued in step S5 by further reducing the already reduced operating power Pred1 by a power reduction to a reduced operating power Pred2. Before this, a check is carried out in step S11 whether the reduced operating power Pred is greater than zero. Otherwise, the laser diode is switched off in step S12.

Depending on the application, the reduction in operating power Pb occurs in constant power reductions or in variable power reductions.

In the case of variable power reductions, it is intended that the power reductions are increased when a temperature difference ΔTis between the measured temperature Ti above the temperature threshold and the temperature threshold value Ts increases. The power reductions are in the range of 5% Pmax≤ΔPb≤30% Pmax, where Pmax is the maximum operating power of the laser diode or the set operating power of the laser diode.

Optimally, the operating power Pb is initially reduced in small steps, e.g. 5% Pmax. Depending on the temperature difference ΔTis between the measured temperature Ti above the temperature threshold and the temperature threshold Ts, the laser diode controller regulates whether the power reduction remains constant or is increased. In this way, self-adaptation can be realized so that the laser diode can be operated with the optimal brightness.

From the above it follows that temperature measurements are carried out at time intervals Δt, for example of 30 min. If the measured temperature Ti is above the single temperature threshold Ts, the operating power Pb is further reduced. If the temperature Ti continues to rise, e.g. due to environmental influences, the operating power Pb can be reduced to zero.

However, the temperature comparison immediately after specified time intervals Δt can also be carried out after the laser diode is switched on, i.e. not only when the measured temperature Ti is at least equal to the temperature threshold Ts for the first time.

1. A laser device (10), such as a laser leveling tool, comprising:
at least one laser diode (14) for emitting a laser beam (16, 20), a laser diode controller (24) for controlling at least the operation of the laser diode (14), a temperature sensor (32) for detecting a temperature Ti associated with the laser device (10), such as the internal temperature of the laser device, such as a laser leveling tool, wherein the laser diode controller (24) is configured to operate the at least one laser diode (14) with an operating power Pb and to reduce the operating power Pb of the laser diode (14) to a reduced operating power Pred when the detected temperature Ti reaches a temperature threshold value Ts,
characterized in that
the laser diode controller (24) is configured such that after switching on the laser diode or after the first reduction of the operating power Pb, the temperature Ti is compared with the temperature threshold value Ts at time intervals Δt and in that the operating power Pred of the laser diode (14) is reduced if the temperature Ti is equal to or greater than the temperature threshold value Ts after the comparison is made.

2. The laser device according to claim 1,
characterized in that
the laser diode controller (24) has a timer (30) for setting the time interval Δt, wherein preferably Δt≤60 min, in particular 10 min≤Δt≤45 min, in particular Δt=30 min, and/or in that the time intervals Δt are constant or variable, preferably constant.

3. The laser device according to claim 1,
characterized in that
the temperature threshold Ts is in the range Ts≤Tmax, preferably 70% Tmax≤Ts≤95% Tmax, wherein Tmax is the highest permissible operating temperature of the laser diode (14).

4. The laser device according to claim 1,
characterized in that
the laser diode controller (24) has a control unit (26) and a laser diode driver (28) which are configured to reduce the operating power Pb of the laser diode (14) in steps, linearly or according to a predetermined function.

5. The laser device according to claim 1,
characterized in that
the control unit (26) and/or the laser diode driver (28) is/are configured to adjust, in particular to reduce, the amplitude of the electrical current and/or the voltage of the laser diode (14) and/or a pulse width of the electrical current and/or the voltage.

6. The laser device according to claim 1,
characterized in that
the temperature sensor (32) is arranged in the interior of the laser device (10), in particular adjacent to or in the region of the at least one laser diode (14).

7. A method for controlling a laser device (10), such as a laser leveling tool, comprising the steps:
controlling at least one laser diode (14) by means of a laser diode controller (24) to emit a laser beam (16, 20),
detecting a temperature Ti associated with the laser device (10), such as the internal temperature of the laser leveling tool, by means of a temperature sensor (32),
wherein the laser diode controller (24) operates the laser diode (14) with an operating power Pb and the operating power Pb of the laser diode (14) is reduced to a reduced operating power Pred when the detected temperature Ti reaches a temperature threshold value Ts,
characterized in that
after switching on the laser diode or after the first reduction of the operating power Pb, the temperature Ti is compared with the temperature threshold value Ts at time intervals Δt and in that the operating power Pred of the laser diode (14) is reduced if the temperature Ti is equal to or greater than the temperature threshold value Ts after the comparison is made.

8. The method according to claim 7,
characterized in that
the reduction in operating power Pb occurs step-wise, linearly or according to a predetermined function and/or that the reduction in operating power Pb occurs at constant or variable, preferably constant, time intervals Δt.

9. The method according to claim 7,
characterized in that
the reduction in operating power Pb takes place in constant power reductions or in variable power reductions, wherein the variable power reductions are increased when a temperature difference ΔTis between the measured temperature Ti above the temperature threshold and the temperature threshold value Ts increases.

10. The method according to claim 7,
characterized in that
the power reduction is in the range of 5% Pmax≤ΔPb≤50% Pmax, where Pmax is the maximum operating power of the laser diode or the set operating power of the laser diode.

11. The method according to claim 7,
characterized in that
the power reduction occurs as a function of the temperature difference ΔTis.
